(19) United States
(12) Patent Application Publication
(10) Pub. No.: US 2005/0269904 A1
(43) Pub. Date: Dec. 8, 2005

(54) Thin film bulk acoustic resonator and method of manufacturing the same

(76) Inventor: Shuichi Oka, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/143,807

(22) Filed: Jun. 2, 2005

(30) Foreign Application Priority Data
Jun. 3, 2004 (JP) P2004-166243

(51) Int. Cl. H01L 41/053

(52) U.S. Cl. 310/324

(57) ABSTRACT

A thin film bulk acoustic resonator is provided in which the spurious caused by a lateral vibration mode is reduced.

The thin film bulk acoustic resonator includes a laminated body having a first electrode 12, a piezoelectric layer 13 adjacently formed on an upper surface of the first electrode 12, and a second electrode 14 adjacently formed on an upper surface of the piezoelectric layer 13, and is made such that these first and second electrodes 12 and 14 have boundary surfaces contacting with air, in which the whole end surface of the piezoelectric layer 13 is made to exist inside the first electrode 12 and second electrode 14.

### CROSS REFERENCES TO RELATED APPLICATIONS

The present invention contains subject matter related to Japanese Patent Application JP 2004-166243 filed in the Japanese Patent Office on Jun. 3, 2004, the entire contents of which being incorporated herein by reference.

### BACKGROUND OF THE INVENTION

1. Field of the Invention

The present invention relates to a thin film bulk acoustic resonator suitable for use in a small-sized high frequency filter used for a communication device and a method of manufacturing the thin film bulk acoustic resonator.

2. Description of the Related Art

In recent years, along with high performance and high-speed operation of a communication device such as a mobile phone unit and a PDA (Personal Digital Assistant: personalized handheld information communication) device, further miniaturization and low cost have been required with respect to a high frequency filter operating in a range from several hundreds MHz to several GHz which is incorporated in such communication devices. A filter using a thin film bulk acoustic resonator that can be formed by using semiconductor manufacturing technology is one of high frequency filters which satisfy such requirement.

As a typical example of the thin film bulk acoustic resonator in related art, there is one called an air bridge type shown in FIGS. 1 and 2 which is described in a non-patent reference 1. FIG. 1 is a plan view showing an example of a thin film bulk acoustic resonator of this air bridge type, and FIG. 2 is an A-A line cross-sectional diagram of FIG. 1.

As shown in FIGS. 1 and 2, the thin film bulk acoustic resonator of the air bridge type in related art is provided with a circular lower electrode 3 having a thickness of 0.01 to 0.5 μm with an air layer 2 constituting an air bridge in between on a substrate 1 made of high resistance silicon or high resistance gallium arsenic.

A circular piezoelectric layer 4 having a thickness of approximately 1 to 2 μm is provided on this lower electrode 3, and a circular upper electrode 5 having a thickness of approximately 0.1 to 0.5 μm is provided on this piezoelectric layer 4.

Those lower electrode 3, piezoelectric layer 4 and upper electrode 5 are formed sequentially using a sputtering and deposition technology and various etching technologies using a resist as a mask, which are known in the semiconductor manufacturing technology.

Molybdenum and platinum, for example, are used as the lower electrode 3 and the upper electrode 5, and aluminum nitride and zinc oxide, for example, are used as the piezoelectric layer 4.

A thickness of the air layer 2 directly under an area where those upper electrode 5 and lower electrode 3 overlap with the piezoelectric layer 4 in between (more specifically, an area which operates as an acoustic resonator) is made into 0.5 to 3 μm, and the lower electrode 3 also has a boundary surface contacting with the air similarly to the upper electrode 5.

The air layer 2 is formed by etching and then removing a silicon oxide film, a PSG (Phosphorus Silicate Glass, an oxide film doped with the phosphorus) film, a BPSG (Boron Phosphorus Silicate Glass, a silicate glass containing born and phosphorus) film, an SOG film, and the like, through via holes 6 as shown in FIGS. 1 and 2.

In FIG. 1, a reference numeral 3a denotes signal wiring connected to the lower electrode 3, and a reference numeral 5a denotes signal wiring connected to the upper electrode 5.

Next, an explanation is made with respect to an operation of the thin film bulk acoustic resonator shown in FIGS. 1 and 2.

When an electric field is generated by applying a voltage between the upper electrode 5 and the lower electrode 3, the piezoelectric layer 4 converts part of electric energy into kinetic energy in the form of an elastic wave (hereinafter, described as a sound wave).

The kinetic energy is propagated in the direction of a film thickness of the piezoelectric layer 4, which is the vertical direction to electrode surfaces of the upper electrode 5 and the lower electrode 3, and is converted again into electric energy. In the conversion process of electric/kinetic energy, there exists a specific frequency having excellent efficiency, and when an alternating voltage having this frequency is applied, the thin film bulk acoustic resonator shows an extremely low impedance.

The specific frequency is generally called a resonance frequency γ, and when the existence of both the upper electrode 5 and lower electrode 3 is disregarded, the value γ as a first approximation is given as
γ=V/2t
, where V is a speed of the sound wave within the piezoelectric layer 4, and t is the thickness of the piezoelectric substrate 4.

When a wavelength of the sound wave is λ,
V=γλ
is obtained, and accordingly
t=λ/2
is obtained.

This indicates that the sound wave induced within the piezoelectric layer 4 repeatedly reflects upward and downward on the boundary surface of the piezoelectric layer 4 with the upper electrode 5 and the boundary surface of the piezoelectric layer 4 with lower electrode 3, and a standing wave corresponding to half the wavelength thereof is formed.

In other words, the resonance frequency is obtained when a frequency of a sound wave in which a standing wave of half the wavelength is existing coincides with a frequency of the alternating voltage applied from the outside.

A band-pass filter having a plurality of thin film bulk acoustic resonators assembled into a ladder form and passing only an electric signal in a desired frequency band with low loss is disclosed in the non-patent reference 1 as the one which utilizes extremely small impedance of the thin film bulk acoustic resonator at the resonance frequency.

Although the thin film acoustic resonator utilizes a sound wave 7 having a vibration mode rising in the vertical direction to the electrode surfaces as described above (hereinafter, called a main vibration mode), as shown in FIG. 3 (practically similar structure to the example of FIGS. 1 and 2) for example, a sound wave 8 having a vibration mode propagating in a parallel direction to the electrode surfaces (hereinafter, called a lateral vibration mode) is also induced.

When a standing wave is formed by the sound wave 8 of the lateral vibration mode which repeatedly reflects on boundary surfaces where an acoustic impedance changes greatly such as a vertical plane 9 within the piezoelectric layer 4 at an edge of the upper electrode 5 and an end surface of the piezoelectric layer 4, the resonance characteristic and quality factor of the thin film bulk acoustic resonator or of a filter using this thin film bulk acoustic resonator is greatly deteriorated.

Specifically, since the sound wave 8 of the lateral vibration mode propagates a long distance in comparison with the sound wave 7 of the main vibration mode, the frequency of the sound wave 8 of the lateral vibration mode becomes considerably lower than the frequency of the sound wave of the main vibration mode that is the resonance frequency γ, however there is a case where a harmonic component of the sound wave 8 of the lateral vibration mode has a frequency in the vicinity of the resonance frequency γ and a noise called spurious may be generated in the resonance characteristic of this thin film bulk acoustic resonator. In addition, when constituting a band-pass filter, a ripple is generated at a passing frequency band to cause unnecessary large insertion loss.

In the past, in order to improve the spurious caused by the lateral vibration mode, there has been proposed an improved structure in which the end surface of the piezoelectric layer 4 is formed not vertically on the outside of the upper electrode 5 as shown in FIG. 4 (refer to the patent reference 1). When the end surface of the piezoelectric layer 4 is made into a shape not vertical, the sound wave 8 of the lateral vibration mode reaching this end surface is dispersed, so that the standing wave of the lateral vibration mode is not easily generated.

[Patent reference 1] Published Japanese Patent Application No. 2003-505906.

[Non-patent reference 1] K. M. Lakin “Thin film resonator and filters” Proceedings of the 1999 IEEE Ultrasonics Symposium, Vol. 2, pp 895-906, and 17-20 Oct. 1999.

### SUMMARY OF THE INVENTION

Although the sound wave 8 of the lateral vibration mode reaching the end surface of the piezoelectric layer 4 is dispersed in the description of the patent reference 1, a large amount of the reflected sound wave 8 of the lateral vibration mode is generated not on the end surface of the piezoelectric layer 4 but on the plane 9 that is vertical to the edge of the upper electrode 5 as shown in FIG. 4, and therefore there is an inconvenience that effectiveness obtained by making the piezoelectric layer 4 on the outside of the upper electrode 5 into the shape not vertical is insufficient to improve the spurious caused by the lateral vibration mode.

There is a need for reducing the spurious caused by a lateral vibration mode.

A thin film bulk acoustic resonator according to an embodiment of the present invention includes a laminated body formed of a first electrode, a piezoelectric layer adjacently formed on the upper surface of the first electrode, and a second electrode adjacently formed on the upper surface of the piezoelectric layer, and boundary surfaces where the first and second electrodes contact with air, in which at least a part of the end surface of the piezoelectric layer is made to exist inside the first electrode or of the second electrode.

A method of manufacturing the thin film bulk acoustic resonator according to an embodiment of the present invention includes the steps of: forming a level difference on a substrate to become an air layer, forming a first sacrifice layer on the level difference, forming a lower electrode of a predetermined shape which straddles the first sacrifice layer on the first sacrifice layer and on the substrate, forming a piezoelectric layer having a taper-shaped end surface, at least a part of lower shape of which is positioned inside the lower electrode, forming a second sacrifice layer of a predetermined shape on an outer circumference of the end surface of the piezoelectric layer, forming an upper electrode having a shape in which at least a part of upper shape of the piezoelectric layer is positioned inside thereof on the piezoelectric layer and on this second sacrifice layer, and removing the first and second sacrifice layers.

Further, the thin film bulk acoustic resonator according to another embodiment of the present invention includes a laminated body formed of a first electrode, a piezoelectric layer adjacently formed on the upper surface of the first electrode, and a second electrode adjacently formed on the upper surface of the piezoelectric layer, and boundary surfaces where the first and second electrodes contact with air, in which the whole end surface of the piezoelectric layer is made to exist inside the first electrode and of the second electrode.

A method of manufacturing the thin film bulk acoustic resonator according to another embodiment of the present invention includes the steps of: forming a level difference on a substrate to become an air layer, forming a first sacrifice layer on the level difference, forming a lower electrode of a predetermined shape which straddles the first sacrifice layer on the first sacrifice layer and on the substrate, forming a piezoelectric layer having a taper-shaped end surface, the whole of lower shape of which is positioned inside the lower electrode, forming a second sacrifice layer having a predetermined shape on an outer circumference of the end surface of the piezoelectric layer, forming an upper electrode having a shape in which the whole upper shape of the piezoelectric layer is positioned inside thereof on the piezoelectric layer and on this second sacrifice layer, and removing the first and second sacrifice layers.

According to embodiments of the present invention, the end surface of the piezoelectric layer is positioned inside the upper electrode and the lower electrode, no piezoelectric layer portion corresponding to the end portions of the upper electrode and the lower electrode exists, reflection of a sound wave of a lateral vibration mode on these portions is eliminated, and also the end surface of the piezoelectric layer is made into a shape that is not vertical, for example, a tapered-shape, and thereby the sound wave of the lateral vibration mode reflects only on the end surface of the piezoelectric layer to be dispersed, and accordingly the spurious caused by the lateral vibration mode can be reduced.

### BRIEF DESCRIPTION OF THE DRAWINGS

FIG. 1 is a plan view showing an example of a thin film bulk acoustic resonator in related art;

FIG. 2 is an A-A line sectional view of FIG. 1;

FIG. 3 is a sectional view for explaining an example in related art;

FIG. 4 is a sectional view for explaining an example in related art;

FIG. 5 is an I-I line sectional view of FIG. 6 showing an embodiment of a thin film bulk acoustic resonator according to the present invention;

FIG. 6 is a plan view of FIG. 5;

FIG. 7 is a sectional view used for simulation according to an embodiment of the present invention;

FIG. 8 is a sectional view for explaining a manufacturing method according to an embodiment of the present invention;

FIG. 9 is a sectional view for explaining a manufacturing method according to an embodiment of the present invention;

FIG. 10 is a sectional view for explaining a manufacturing method according to an embodiment of the present invention;

FIG. 11 is a sectional view for explaining a manufacturing method according to an embodiment of the present invention;

FIG. 12 is a sectional view for explaining a manufacturing method according to an embodiment of the present invention;

FIG. 13 is a sectional view for explaining a manufacturing method according to an embodiment of the present invention;

FIG. 14 is a sectional view for explaining a manufacturing method according to an embodiment of the present invention;

FIG. 15 is a diagram for explaining an embodiment of the present invention; and

FIG. 16 is a diagram for explaining an example in related art.

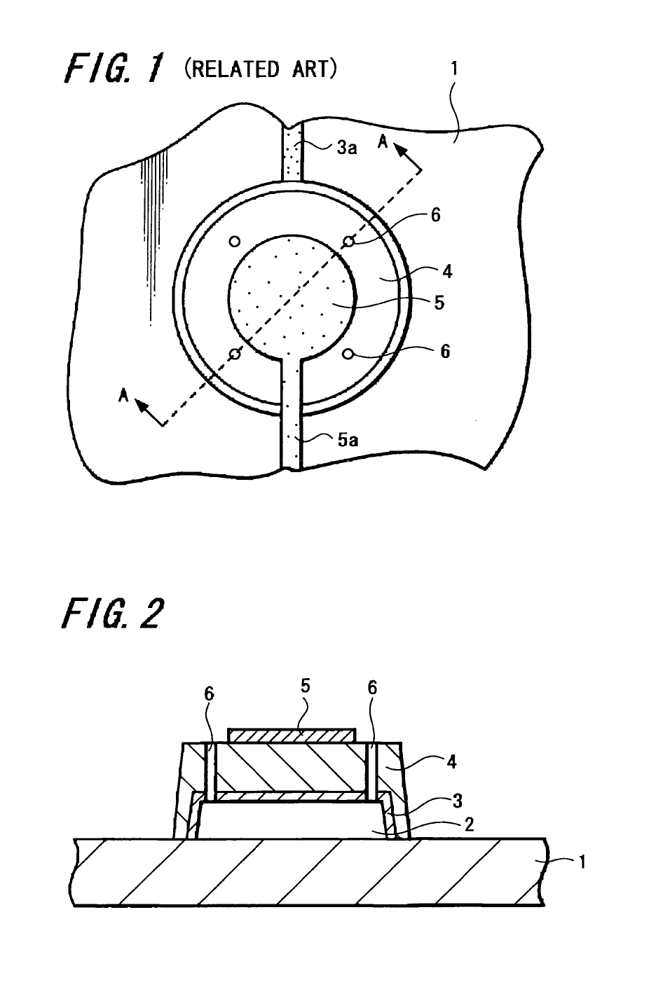

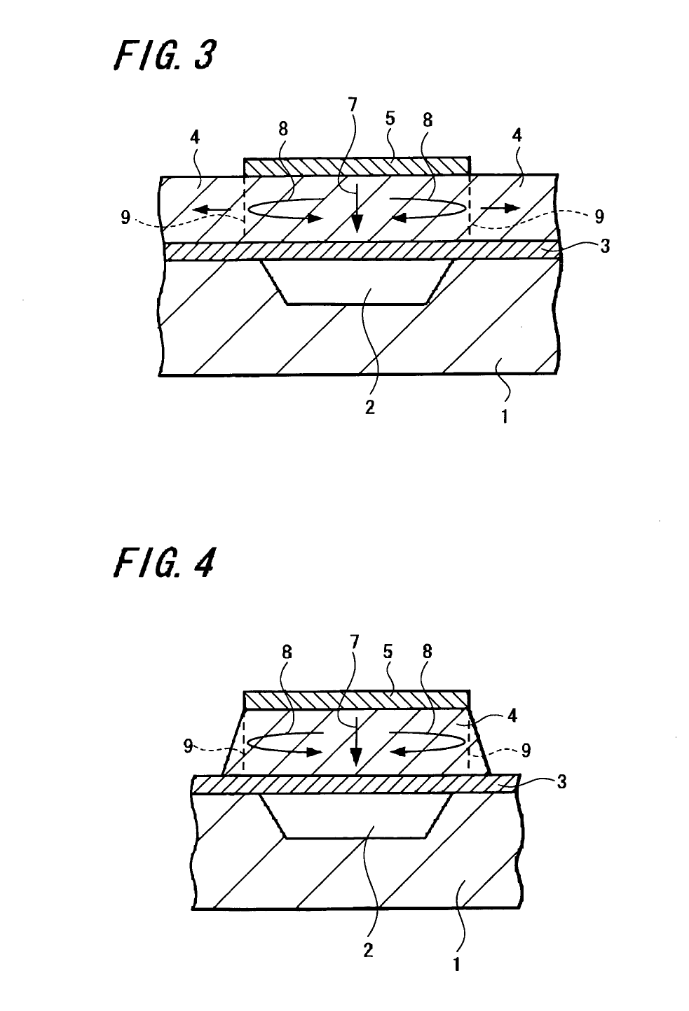

### DESCRIPTION OF THE PREFERRED EMBODIMENTS

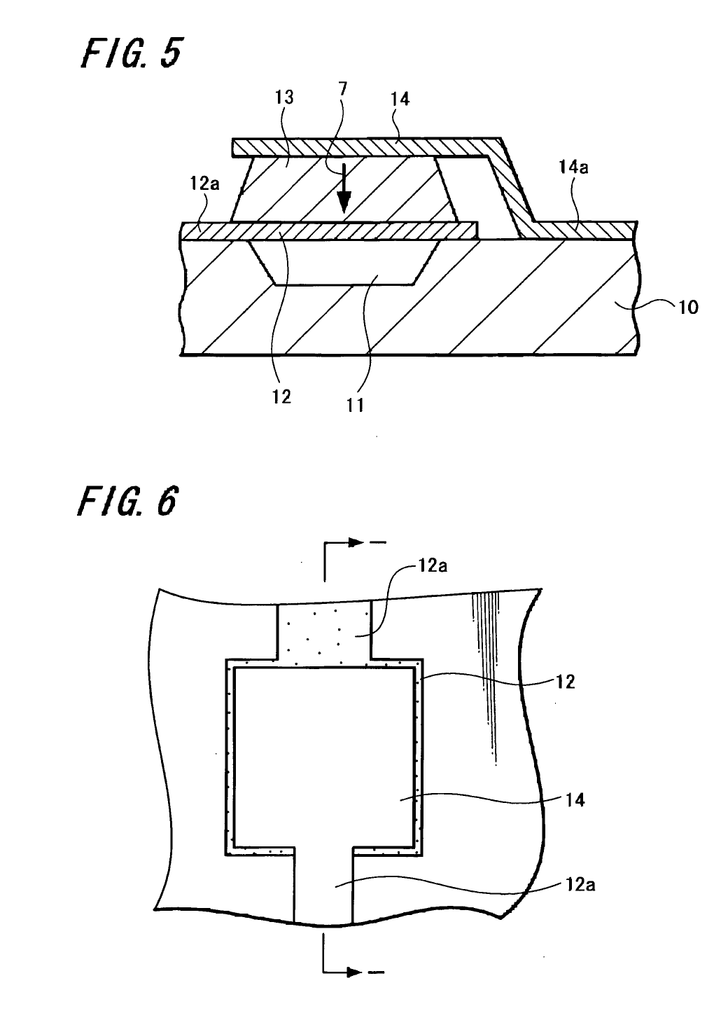

Hereinafter, embodiments of a thin film bulk acoustic resonator and a method of manufacturing thereof according to the present invention will be explained by referring to FIGS. 5 through 14.

A thin film bulk acoustic resonator according an embodiment of the present invention is as shown in FIGS. 5 through 7, in which FIG. 6 is a plan view and FIG. 5 is an I-I sectional view of FIG. 6. The thin film bulk acoustic resonator according to this embodiment shown in FIGS. 5 and 6 includes a laminated body having a lower electrode 12 formed on a substrate 10 through an air layer 11, a piezoelectric layer 13 adjacently formed on an upper surface of the lower electrode 12, and an upper electrode 14 adjacently formed on an upper surface of the piezoelectric layer 13, such that the lower electrode 12 and upper electrode 14 have boundary surfaces contacting with air, in which the whole end surface of the piezoelectric layer 13 is made to exist inside the lower electrode 12 and upper electrode 14. In FIG. 6, a reference numeral 12a denotes signal wiring connected to the lower electrode 12, and a reference numeral 14a denotes signal wiring connected to the upper electrode 14.

Next, an embodiment of a method of manufacturing the thin film bulk acoustic resonator shown in FIGS. 5 through 7 is explained by referring to FIGS. 8 through 14.

First, as shown in FIG. 8, a quadrangular hole (level difference) 11a of a predetermined size to be the air layer 11 later on is formed in the substrate 10 made of high resistance silicon or high resistance gallium arsenic. A depth of this hole (level difference) 11a is made to around 0.5 to 3 μm.

Next, a sacrifice layer 20 thicker than the depth of the hole (level difference) 11a is formed in the hole (level difference) 11a. A silicon oxide film, a PSG film, a BPSG film, an SOG film, or the like is used as the sacrifice layer 20. After the sacrifice layer 20 is formed, etch-back is performed to planarize a surface by CMP (Chemical Mechanical Polishing) and the like, as shown in FIG. 9.

Subsequently, as shown in FIG. 10, the lower electrode 12 of a predetermined size having a predetermined shape of, for example, a quadrangle and straddling the sacrifice layer 20 is formed on the sacrifice layer 20 and on the substrate 10 using the sputter deposition technology known in the semiconductor manufacturing technology and using various etching technologies using a resist as a mask. Molybdenum, platinum, or the like is used as the lower electrode 12. A thickness of the lower electrode 12 is made to around 0.1 to 0.5 μm.

Next, a piezoelectric layer having a thickness of approximately 1 to 2 μm is formed using a sputter deposition technology. Aluminum nitride or zinc oxide, for example, is used as the piezoelectric layer. Subsequently, as shown in FIG. 11, a piezoelectric layer 13 having a taper-shaped end surface of approximately 50° is formed by etching using a developing solution.

In this case, the whole lower shape of the piezoelectric layer 13 is formed inside the lower electrode 12.

Next, a sacrifice layer 21 thicker than an added value of the thickness of the lower electrode 12 and that of the piezoelectric layer 13 is formed on the upper surface of the substrate 10 around an outer circumference of the piezoelectric layer 13 on the lower electrode 12 and substrate 10. The silicon oxide film, the PSG film, the BPSG film, the SOG film, or the like is used as the sacrifice layer 21.

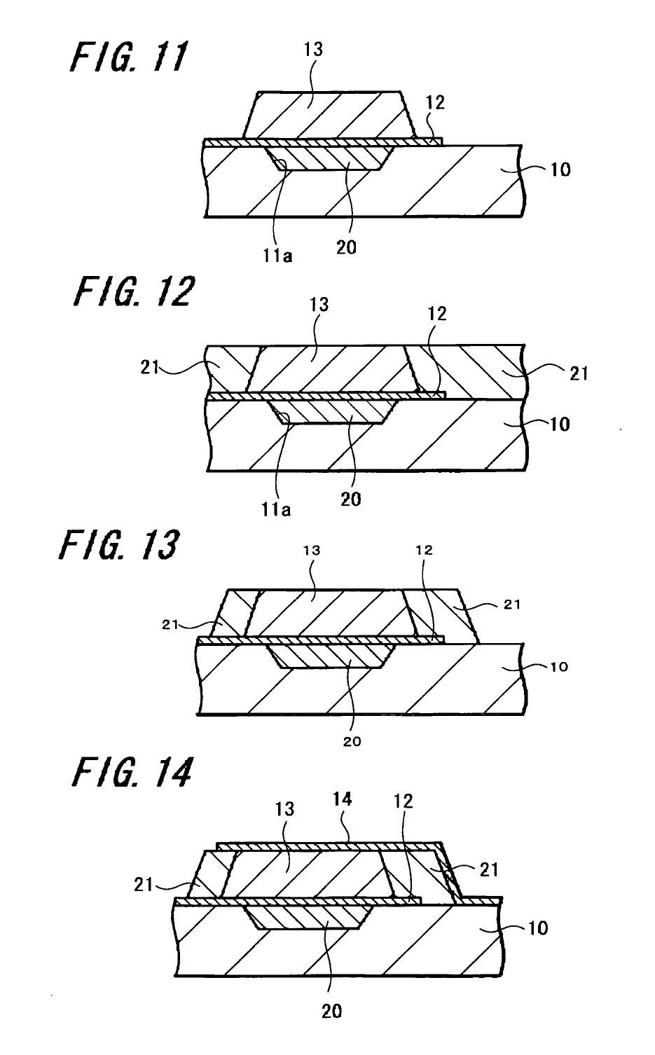

After forming the sacrifice layer 21, etch-back is performed to planarize an upper surface thereof by the CMP or the like as shown in FIG. 12. Next, the sacrifice layer 21 is processed into a predetermined shape as shown in FIG. 13.

Subsequently, an upper electrode 14 is formed on the piezoelectric layer 13 and sacrifice layer 21 using sputter deposition technology. In this case, the upper electrode 14 is made into such a shape that the whole upper shape of the piezoelectric layer 13 is positioned inside the upper electrode 14 (refer to FIG. 14). Molybdenum, platinum, or the like is used as the upper electrode 14, and a thickness thereof is made to 0.1 to 0.5 μm.

Subsequently, the sacrifice layers 20 and 21 are removed by HF etching, and the thin film bulk acoustic resonator as shown in FIG. 5 is obtained.

Next, an operation of the thin film bulk acoustic resonator shown in FIGS. 5 through 7 is explained.

When an electric field is generated by applying a voltage between the upper electrode 14 and lower electrode 12, the piezoelectric layer 13 converts part of electric energy into kinetic energy in the form of an elastic wave (hereinafter, described as a sound wave).

This kinetic energy is propagated in the direction of the film thickness of the piezoelectric layer 13 which is a vertical direction to electrode surfaces of the upper electrode 14 and the lower electrode 12, and is converted again into electric energy. In the conversion process of electric/kinetic energy, there exists a specific frequency having excellent efficiency, and when an alternating voltage having this frequency is applied, the thin film bulk acoustic resonator shows an extremely low impedance.

The specific frequency is generally called a resonance frequency γ, and when the existence of both the upper electrode 14 and lower electrode 12 is disregarded, the value γ as a first approximation is given as
γ=V/2t
, where V is a speed of the sound wave within the piezoelectric layer 4, and t is the thickness of the piezoelectric substrate 4.

When a wavelength of the sound wave is λ,
V=γλ
is obtained, and accordingly
t=λ/2
is obtained.

This indicates that the sound wave induced within the piezoelectric layer 13 repeatedly reflects upward and downward on the boundary surface of the piezoelectric layer 13 with the upper electrode 14 and the boundary surface of the piezoelectric layer 13 with lower electrode 12, and a standing wave corresponding to half the wavelength thereof is formed.

In other words, the resonance frequency is obtained when a frequency of a sound wave in which a standing wave of half the wavelength is existing coincides with a frequency of the alternating voltage applied from the outside.

Further, according to this embodiment, since the end surface of the piezoelectric layer 13 is made into the tapered-shape; the lower shape of the piezoelectric layer 13 is made to exist inside the lower electrode 12; and the upper shape of the piezoelectric layer 13 is made to exist inside the upper electrode 14 as shown in FIGS. 5 through 7, there is no portion of piezoelectric layer 13 corresponding to respective end portions of the upper electrode 14 and the lower electrode 12, there is no reflection of the sound wave of the lateral vibration mode on this portion (surface), and also since the end surface of the piezoelectric layer 13 is made into the tapered-shape instead of the vertical plane, the sound wave of the lateral vibration mode is dispersed, and the spurious caused by the lateral vibration mode can be reduced.

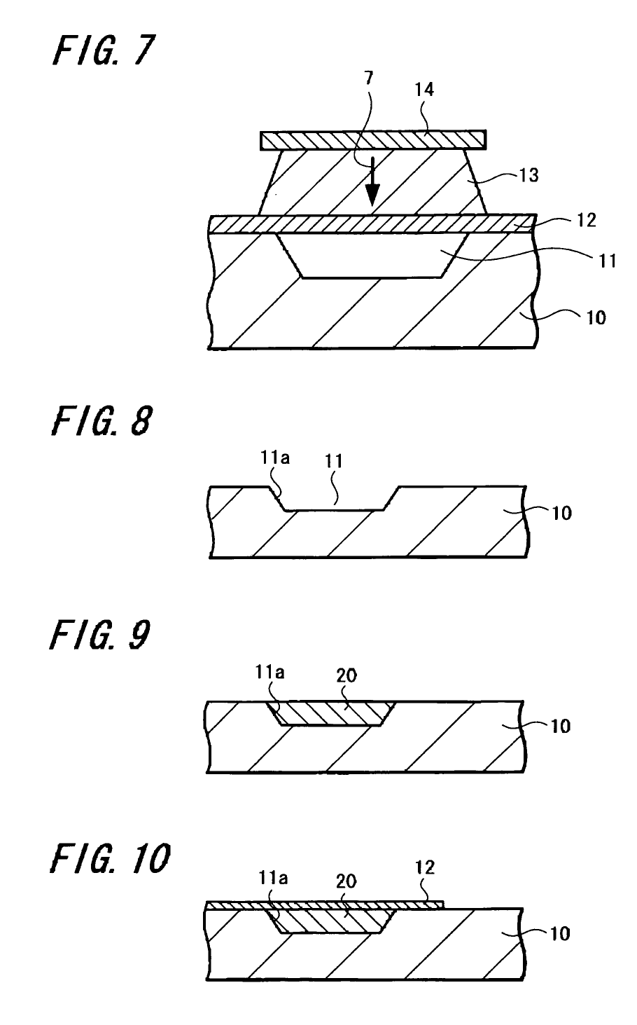

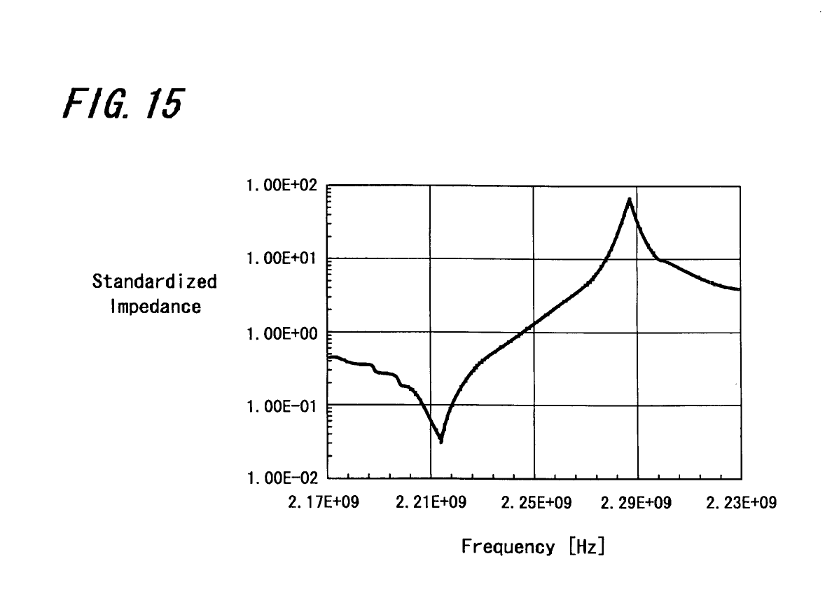

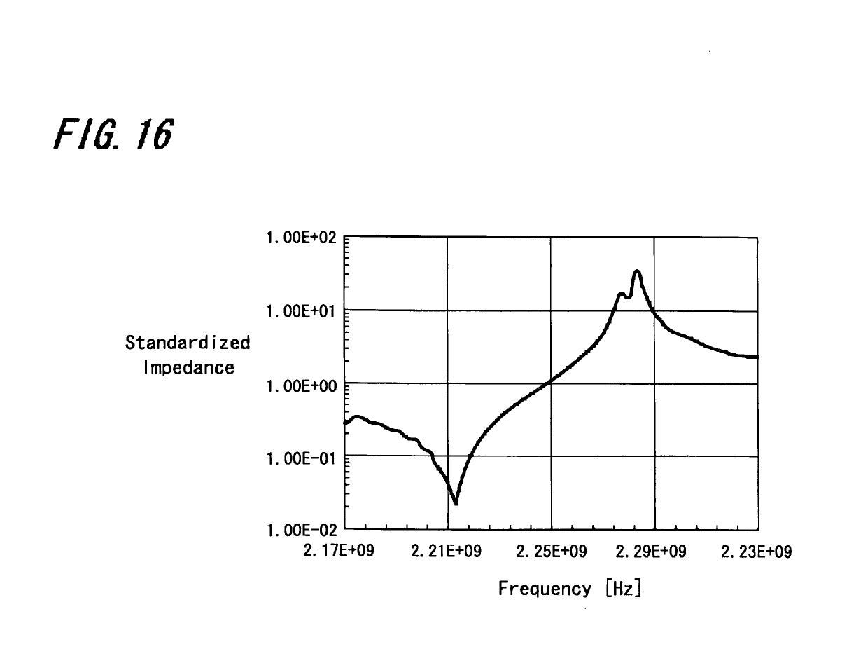

A result verified by simulation according to the finite element method is described hereinafter. FIG. 15 shows a result of simulation performed with respect to a thin film bulk acoustic resonator having a structure shown in FIG. 7 as a structure of this embodiment. For the comparison, a result of simulation performed with respect to the thin film bulk acoustic resonator having the structure of related art shown in FIG. 4 is shown in FIG. 16.

Hereupon, a value of an impedance shown is standardized using a capacity value when the thin film bulk acoustic resonator is regarded simply as a parallel plate capacity.

As constants of a basic structure of the thin film bulk acoustic resonator for both of the embodiment in the present invention and the example in related art, the thickness of the molybdenum electrode used as the upper electrodes 14 and 5 is 0.3 μm, the thickness of the aluminum nitride layer used as the piezoelectric layers 13 and 4 is 1 μm, and the upper electrodes 14 and 5 are made into a regular tetragon of 100 μm×100 μm.

As shown in FIG. 16, in the case of the example of related art, the impedance varies around 2.17 GHz and around an anti-resonant frequency of about 2.28 GHz like a noise, and the spurious caused by the lateral vibration mode is recognized.

On the other hand, in the case of the embodiment according to the present invention, as shown in FIG. 15, the spurious in the vicinity of the anti-resonant frequency is reduced and a waveform becomes comparatively smooth. This indicates that the spurious caused by the lateral vibration mode is reduced in the embodiment.

Furthermore, although it is described in the above-described embodiment that the whole end surface of the piezoelectric layer 13 exists inside both the lower electrode 12 and the upper electrode 14, a similar operational effect to the above-described embodiment can be obtained as long as a part of the lower shape and upper shape of the piezoelectric layer 13 exists inside the lower electrode 12 and upper electrode 14.

In addition, although the end surface of the piezoelectric layer 13 is made into the tapered-shape in the above-described embodiment, a similar operational effect to the above-described embodiment can be obtained as long as the end surface is made into a shape other than the vertical plane.

Needless to say, the present invention is also applicable to a stacked thin film bulk acoustic resonator which is a modification of the thin film bulk acoustic resonator.

It should be understood by those skilled in the art that various modifications, combinations, sub-combinations and alterations may occur depending on design requirements and other factors insofar as they are within the scope of the appended claims or the equivalents thereof.

1. A thin film bulk acoustic resonator comprising:
a laminated body including a first electrode, a piezoelectric layer adjacently formed on the upper surface of the first electrode, and a second electrode adjacently formed on the upper surface of the piezoelectric layer, and
boundary surfaces where said first and second electrodes contact with air,
wherein at least a part of an end surface of said piezoelectric layer exists inside said first electrode or inside said second electrode.

2. A thin film bulk acoustic resonator according to claim 1,
wherein the end surface of said piezoelectric layer is not vertical.

3. A thin film bulk acoustic resonator according to claim 1,
wherein the end surface of said piezoelectric layer has a tapered-shape.

4. A method of manufacturing a thin film bulk acoustic resonator, comprising the steps of:
forming a level difference on a substrate to become an air layer;
forming a first sacrifice layer on the level difference;
forming a lower electrode of a predetermined shape straddling said first sacrifice layer on said first sacrifice layer and on said substrate;
forming a piezoelectric layer having a taper-shaped end surface and at least a part of lower shape of which is positioned inside said lower electrode;
forming a second sacrifice layer having a predetermined shape on an outer circumference of the end surface of said piezoelectric layer;
forming on said piezoelectric layer and on said second sacrifice layer an upper electrode having a shape in which at least a part of upper shape of said piezoelectric layer is positioned inside thereof; and
removing said first and second sacrifice layers.

5. A thin film bulk acoustic resonator comprising:
a laminated body including a first electrode, a piezoelectric layer adjacently formed on the upper surface of the first electrode, and a second electrode adjacently formed on the upper surface of the piezoelectric layer, and
boundary surfaces where said first and second electrodes contact with air,
wherein the whole end surface of said piezoelectric layer exists inside said first electrode and inside said second electrode.

6. A thin film bulk acoustic resonator according to claim 5,
wherein the end surface of said piezoelectric layer is not vertical.

7. A thin film bulk acoustic resonator according to claim 5,
wherein the end surface of said piezoelectric layer has a tapered-shape.

8. A method of manufacturing a thin film bulk acoustic resonator, comprising the steps of:
forming a level difference on a substrate to be an air layer;
forming a first sacrifice layer on the level difference;
forming a lower electrode of a predetermined shape straddling said first sacrifice layer on said first sacrifice layer and on said substrate;
forming a piezoelectric layer having a taper-shaped end surface and the whole of lower shape of which is positioned inside said lower electrode;
forming a second sacrifice layer having a predetermined shape on an outer circumference of the end surface of said piezoelectric layer;
forming on said piezoelectric layer and on said second sacrifice layer an upper electrode having a shape in which the whole of the upper shape of said piezoelectric layer is positioned inside thereof; and
removing said first and second sacrifice layers.
